(19) United States
(12) Patent Application Publication
(10) Pub. No.: US 2025/0381583 A1
(43) Pub. Date: Dec. 18, 2025

(54) METHOD FOR MANUFACTURING SILICEOUS FILM

(71) Applicant: Merck Patent GmbH, Darmstadt (DE)

(72) Inventors: Masanobu Hayashi, Hamamatsu (JP); Ikuya Ichie, Shizuoka (JP); Masamichi Kurokawa, Shizuoka (JP)

(21) Appl. No.: 19/315,040

(22) Filed: Aug. 29, 2025

Related U.S. Application Data
(63) Continuation of application No. PCT/EP2024/054861, filed on Feb. 27, 2024.

(30) Foreign Application Priority Data
Mar. 1, 2023 (JP) 2023-031162

(51) Int. Cl. B05D 1/00; B05D 3/04; C09D 183/04

(52) U.S. Cl. CPC B05D 1/005; B05D 3/0453; C09D 183/04; B05D 2203/30; B05D 2518/12

(57) ABSTRACT

A method for manufacturing a siliceous film includes:
a step of applying a siliceous film composition above a substrate having grooves to form a composition layer;
a step of exposing the composition layer to an atmosphere containing a basic compound gas and water vapor; and
a step of heating the substrate to cure the composition layer,
wherein the basic compound is ammonia, a quaternary ammonium compound or a combination of any of these.

### CROSS-REFERENCE TO RELATED APPLICATIONS

This application is a Continuation under 35 USC § 111 (a) of International Patent Application No. PCT/EP2024/054861 filed Feb. 27, 2024, which claims priority to Japanese Patent Application No. JP2023-031162 filed Mar. 1, 2023. The entire contents of these applications are incorporated herein by reference in their entirety.

### BACKGROUND OF THE INVENTION

### Technical Field

The present invention relates to a method for manufacturing a siliceous film.

### Background Art

In the manufacturing of electronic devices, especially semiconductor devices, interlayer insulating films are formed between transistor elements and bit lines, between bit lines and capacitors, between capacitors and metal wiring, and between multiple metal wirings, etc. Furthermore, an insulating material may be embedded in isolation trenches formed on the substrate surface and the like. A siliceous film is often used as such an insulating film.

For the methods for forming a siliceous film, chemical vapor deposition method (CVD method), sol-gel method, and a method for applying and baking a liquid composition comprising a silicon-containing polymer are used. Among these methods, a method for forming a siliceous film using a liquid composition is often used because it is relatively simple. A siliceous film can be formed by applying a composition comprising a silicon-containing polymer such as polysilazane on the surface of a substrate and converting it into silica by heating and the like.

In order to form a dense siliceous film and improve the efficiency of the process, it has been proposed to include a step of contacting with a vapor containing an amine compound during silica conversion (for example, JP H9-183663 A and JP 2001-89126 A).

When filling grooves with a liquid composition to form a coating film, on the case that the grooves have a complex structure or are deep, the stress on the film becomes uneven during heating for curing and it becomes that cracks likely generate or it becomes difficult to form a dense cured film. As semiconductor integrated circuits become more highly integrated, there is a need for a method for uniformly filling trenches that are deeper and have high aspect ratios.

### SUMMARY OF THE INVENTION

### Problems to be Solved by the Invention

The present inventors thought that there are one or more problems that still need improvement in the method for manufacturing a siliceous film on a substrate having grooves. Examples of these include the following:

When the grooves become deeper, cracks are more likely to generate; during heating for curing, shrinkage of film thickness is not suppressed sufficiently; during heating for curing, low molecular weight components of the polymer scatter; it is difficult to form a thick siliceous film; the process for forming a siliceous film is inefficient; the dry etching rate of the siliceous film formed in the grooves is not constant in the depth direction; the difference in the wet etching rate of the siliceous film formed in the grooves is large between the upper and lower parts of the grooves.

### Means for Solving the Problems

The method for manufacturing a siliceous film according to the present invention comprises the following steps:
a step of applying a siliceous film composition above a substrate having grooves to form a composition layer;
a step of exposing the composition layer to an atmosphere containing a basic compound gas and water vapor; and
a step of heating the substrate to cure the composition layer,
wherein the basic compound is ammonia, a quaternary ammonium compound or a combination of any of these.

The method for manufacturing an element of an electronic device according to the present invention comprises the above method.

### Effects of the Invention

According to the present invention, it is possible to expect one or more of the following effects.

Generation of cracks are suppressed even when the grooves are deep; shrinkage of the film thickness is suppressed sufficiently during heating for curing; scattering of low molecular weight components of the polymer can be suppressed during heating for curing; a sufficiently thick siliceous film can be formed; a siliceous film can be formed efficiently; the dry etching rate of the siliceous film formed in the grooves becomes constant in the depth direction; the difference in wet etching speed of the siliceous film formed in the grooves can be reduced between the upper and lower parts of the grooves.

### BRIEF DESCRIPTION OF THE DRAWINGS

FIG. 1 is an electron micrograph showing the state that no cracks generate in the area having grooves.

FIG. 2 is an electron micrograph showing the state that a crack generates in the area having grooves.

### DETAILED DESCRIPTION OF THE INVENTION

### Mode for Carrying Out the Invention

### Definitions

Unless otherwise specified in the present specification, the definitions and examples described below are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The alkyl means a group obtained by removing any one hydrogen from a linear, branched or cyclic saturated hydrocarbon and includes a linear alkyl, branched alkyl or cycloalkyl and optionally includes a linear or branched alkyl in the cyclic structure as a side chain. The aryl means a group obtained by removing any one hydrogen from an aromatic hydrocarbon.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has plural types of repeating units, these repeating units copolymerize. These copolymerization can be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent or another component.

Hereinafter, embodiments of the present invention are described in detail.

### Method for Manufacturing Siliceous Film

The method for manufacturing a siliceous film according to the present invention comprises the following steps:
a step of applying a siliceous film composition above a substrate having grooves to form a composition layer;
a step of exposing the composition layer to an atmosphere containing a basic compound gas and water vapor; and
a step of heating the substrate to cure the composition layer.

### Step (a)

The step (a) is a step of applying a siliceous film composition above a substrate having grooves to form a composition layer.

In the present invention, the substrate can be a single layer or a laminate. The shape of the groove is not particularly limited, but in the present invention, since it is characterized in that the composition can easily penetrate into narrow grooves and a uniform cured film can be formed even inside the grooves, a substrate having grooves and holes having sufficiently high aspect ratio is preferred. The aspect ratio is preferably 3 to 50, more preferably 5 to 30. The shape of the groove is not particularly limited, and the cross section can be rectangular, forward tapered shape, reverse tapered shape, curved surface shape, or any other shape. Further, both end portions of the groove can be open or closed.

Substrates having grooves include, for example, substrates for electronic devices comprising transistor devices, bit lines, capacitors and the like. In the manufacture of such electronic devices, following the steps such as a step of forming an insulating film called PMD (between a transistor device and a bit line, between a transistor device and a capacitor, between a bit line and a capacitor, or between a capacitor and a metal wiring) or an insulating film called IMD between plural metal wirings, or a step of filling isolation trenches, a through-hole forming step that forms a hole passing through the material filled in fine grooves may be included.

A siliceous film composition is applied above a substrate, and in the present invention, the siliceous film composition can be applied directly on the substrate, or can be applied above the substrate via one or more interlayers.

There are no particular restrictions on the method for coating the substrate, and conventional coating methods, such as spin coating method, dip coating method, spray coating method, transfer coating method and slit coating method, are included.

The preferred siliceous film compositions are described later.

A composition layer is formed by applying the siliceous film composition, and at this time, if necessary, a drying step can be performed by spin drying, reduced pressure or prebaking.

In a preferred embodiment, between the step (a) and the step (b), a step of heating (prebaking step) the substrate above which the composition layer is formed at 50° C. or higher, more preferably at 60 to 120° C. is further contained. The prebaking step is preferably performed under a nitrogen atmosphere.

The siliceous film composition is preferably applied in an amount that sufficiently fills the grooves in the substrate. At the state in which an amount of the siliceous film composition that sufficiently fills the grooves of the substrate is applied, in which the groove portions are filled with the siliceous film composition, and in which a composition layer is formed also on the portions of the substrate surface having no grooves, the composition layer is formed to be sufficiently thick in the portions having no grooves. For flattening, a step of removing a surplus part of the coating film can be further contained. This removing step is preferably performed before the drying step, and more preferably, this removing step is performed after forming the composition layer and before prebaking.

### Step (b)

The step (b) is a step of exposing the composition layer formed in the step (a) to an atmosphere containing a basic compound gas and water vapor (hereinafter sometimes referred to as basic atmosphere).

The basic compound is ammonia, a quaternary ammonium compound or a combination of any of these, and preferably selected from the group consisting of ammonia, tetramethylammonium hydroxide, tetraethylammonium hydroxide (TEAH), tetrapropylammonium hydroxide and tetrabutylammonium hydroxide, and more preferably ammonia.

The step (b) is preferably performed under atmospheric pressure (101.3 kPa).

The partial pressure of water vapor in a basic atmosphere is preferably 20 to 90 kPa, more preferably 25 to 90 kPa, and further preferably 25 to 85 kPa, when the total pressure is 101.3 kPa.

The step (b) is preferably performed at 20 to 200° C., more preferably 50 to 200° C., further preferably 50 to 150° C.

The partial pressure of the basic compound gas in the basic atmosphere is preferably 2 to 50 kPa, more preferably 2 to 30 kPa, and further preferably 10 to 25 kPa, when the total pressure is 101.3 kPa.

The basic atmosphere can comprise components other than the above-mentioned basic compounds and water vapor (hereinafter sometimes referred to as diluent gas), and exemplified embodiments thereof include air, oxygen, nitrogen, nitrous oxide, ozone, helium, argon and the like. The content of the diluent gas is preferably 50 kPa or less, more preferably 40 kPa or less, in the basic atmosphere.

The basic atmosphere can be formed by introducing the above basic compound gas into a processing container and then introducing water vapor, by introducing water vapor into a processing container and then introducing the above basic compound gas, or by introducing an aqueous solution of the above basic compound into a processing container and heating it.

One of the features of the present invention is that, before the step (c) of curing the composition layer, the composition layer is exposed to an atmosphere containing a certain basic compound gas and water vapor. Although this is not to be bound by theory, since the conversion to a siliceous film progresses with a small shrinkage rate by exposing the composition layer to an atmosphere containing the basic compound gas and water vapor, the dimensional changes near the opening of the grooves can be suppressed. As a result, local stress concentration near the opening does not occur and formation of cracks can be suppressed. Due to the low stress film near the opening, in the subsequent curing step (c), the generation of strong tensile stress at the bottom portion of the groove can be suppressed and a constant dry etching rate can be achieved from the opening to the bottom portion of the groove. Further, since hydrates of basic compounds are active species in the reaction that converts the composition layer into a siliceous film with a small shrinkage rate, ammonia and quaternary ammonium compounds exhibit an effect, while triethylamine, which does not form any hydrate, does not exhibit any effect.

### Step (c)

The step (c) is a step of heating the substrate and curing the composition layer, thereby obtaining a siliceous film. The heating temperature in this step is not particularly limited as long as it is a temperature that cures the composition layer. In order to promote the curing reaction and obtain a sufficiently cured film, the curing temperature is preferably 200 to 1,000° C., more preferably 300 to 1,000° C. The heating time is not particularly limited, and is preferably 1 minute to 10 hours, more preferably 1 minute to 180 minutes. The atmosphere during curing varies depending on the composition used, but is preferably a steam atmosphere or a nitrogen atmosphere.

The curing step can also be divided into two or more stages. For example, heating can be first performed at a low temperature (for example, temperature range of 200 to 400° C.) in an atmosphere containing water vapor, and then heating (annealing) can be performed at a higher temperature (for example, 400 to 1,000° C.) in an atmosphere free of water vapor, preferably a nitrogen atmosphere.

The atmosphere having water vapor in the step (c) refers to an atmosphere in which the partial pressure of the water vapor is within the range of 0.5 to 101 kPa when the total pressure is 101.3 kPa, and it has a partial pressure of the water vapor in the range of preferably 1 to 90 kPa, more preferably 1.5 to 80 kPa. Any gas can be used as a component other than the water vapor in an atmosphere containing the water vapor, and exemplified embodiments thereof include air, oxygen, nitrogen, nitrous oxide, ozone, helium, argon and the like, and preferably, the basic compound gas is not contained.

In the present specification, “siliceous film” refers to one having a ratio (O/Si) of the number of oxygen atoms to the number of silicon atoms of 1.20 to 2.50, preferably 1.40 to 2.50, more preferably 1.60 to 2.45. The siliceous film can contain other atoms such as hydrogen, nitrogen, carbon and the like.

The method for manufacturing an electronic device according to the present invention comprises the method described above. The electronic device is preferably a semiconductor device.

### Siliceous Film Composition

The siliceous film composition (hereinafter sometimes referred to as the composition) used in the present invention is not particularly limited as long as it contains components that can form a siliceous film.

As the component capable of forming a siliceous film, it may be a polymer, a polymerizable monomer component, or a mixture thereof. The composition according to the present invention preferably comprises a silicon-containing polymer. In a preferred embodiment of the present invention, the composition used in the present invention comprises a silicon-containing polymer selected from the group consisting of polysilazane, polycarbosilazane and polysiloxazane.

The mass average molecular weight of the silicon-containing polymer is preferably 1,000 to 30,000, more preferably 1,200 to 28,000, further preferably 1,500 to 25,000. In the present invention, the mass average molecular weight means a mass average molecular weight in terms of polystyrene, which can be measured by the gel permeation chromatography based on polystyrene. The same is applied to the other polymers.

The content of the silicon-containing polymer is preferably 10 to 100 mass %, more preferably 15 to 85 mass %, based on the total mass of the composition.

### Polysilazane

The structure of the polysilazane used in the present invention is not particularly limited, and any polysilazane can be freely selected depending on the purpose. The polysilazane has a Si—N bond as a main skeleton, can be either an inorganic compound or an organic compound, and can have a linear, branched, or partially cyclic structure.

Preferably, the polysilazane contains 20 or more, preferably 20 to 350, repeating units selected from the group consisting of the following formulae (1-i) to (1-vi). It is preferable that each repeating unit is directly bonded without intervening repeating units other than (1-i) to (1-vi).

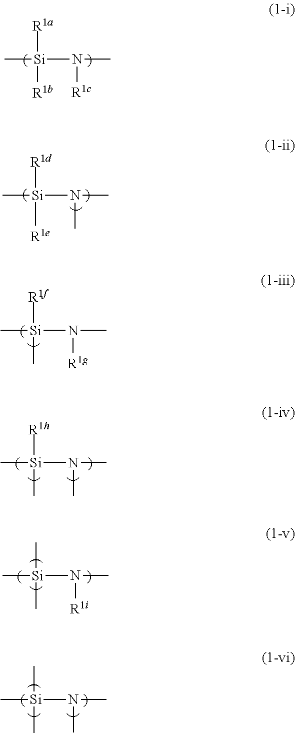

wherein, R^{1a} to R¹ⁱ are each independently hydrogen or C₁₋₄ alkyl.

More preferably, the polysilazane used in the present invention is perhydropolysilazane (hereinafter referred to as PHPS). PHPS is a silicon-containing polymer comprising Si—N bond as a repeating unit and consisting only of Si, N and H. In this PHPS, except Si—N bond, all elements binding to Si and N are H, and any other elements such as carbon or oxygen are not substantially contained. The simplest structure of the perhydropolysilazane is a chain structure having a repeating unit of the following formula:

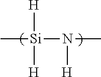

The structure of PHPS is not limited as long as it contains Si—N bonds as the repeating unit and is a silicon-containing polymer consisting only of Si, N and H, and can take various structures other than those exemplified above. PHPS preferably is one having a cyclic structure or a crosslinked structure, particularly a crosslinked structure. The terminal group of the perhydropolysilazane is preferably —SiH₃.

The mass average molecular weight of the polysilazane is preferably 1,200 to 28,000, more preferably 1,500 to 25,000, from the viewpoint of solubility in solvents and reactivity.

### Polycarbosilazane

The structure of the polycarbosilazane used in the present invention is not particularly limited, and any polycarbosilazane can be freely selected depending on the purpose. In the present invention, the polycarbosilazane refers to one that has a C—Si—N structure.

In a preferred embodiment, the polycarbosilazane used in the present invention comprises a repeating unit represented by the following formula (2-i) and a repeating unit represented by the following formula (2-ii).

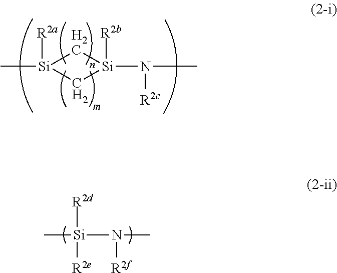

wherein,
R^{2a}, R^{2b} and R^{2c} are each independently a single bond, hydrogen or C₁₋₄ alkyl, preferably a single bond or hydrogen.
R^{2d}, R^{2e} and R^{2f} are each independently a single bond or hydrogen.

Provided that, when R^{2a}, R^{2b}, R^{2d} and R^{2e} are single bonds, they are bonded to N contained in other repeating units, and when R^{2c} and R^{2f} are single bonds, they are bonded to Si contained in other repeating units.

n and m are each independently 1 to 3, preferably 1 or 2, more preferably 1.

The polycarbosilazane is preferably polyperhydrocarbosilazane. The polyperhydrocarbosilazane is one, in which R^{2a}, R^{2b} and R^{2c} are single bonds or hydrogen and no hydrocarbon groups other than (CH₂) n and (CH₂) m in the formula (2-i) are included.

The terminal group of the polycarbosilazane is preferably —SiH₃.

The polycarbosilazane used in the present invention preferably consists substantially of the repeating unit represented by the formula (2-i) and the repeating unit represented by the formula (2-ii). In the present invention, “substantially” means that 95 mass % or more of all structural units contained in the polycarbosilazane are the repeating unit represented by the formula (2-i) and the repeating unit represented by the formula (2-ii). More preferably, the polycarbosilazane contains no repeating units other than the repeating unit represented by the formula (2-i) and the repeating unit represented by the formula (2-ii).

In another preferred embodiment, the polycarbosilazane used in the present invention comprises a repeating unit represented by the formula (2-iii):

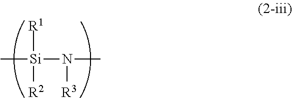

wherein,
R¹ and R² are each independently a single bond, hydrogen, C₁₋₄ alkyl or a linking group represented by the following formulae (a) to (c), and are preferably a single bond, hydrogen or a linking group represented by the formulae (a) to (c). When R¹ and R² are single bonds, they are bonded to N contained in other repeating units, and in the molecule, at least two of R¹ and R² are linking groups represented by the formulae (a) to (c).
R³ is a single bond, hydrogen or C₁₋₄ alkyl, preferably a single bond or hydrogen. When R³ is a single bond, it is bonded to Si contained in other repeating unit.

The linking group represented by the formula (a) is as follows:

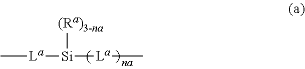

wherein,
R^{a} is each independently hydrogen, C₁₋₆ alkyl, C₁₋₆ alkenyl or C₆₋₁₂ aryl, preferably methyl, ethyl, vinyl, allyl or phenyl.
   L^{a} is each independently C₂₋₈ alkylene or C₆₋₁₄ arylene, preferably C₂₋₆ alkylene, more preferably —CH₂—CH₂— or —CH₂—CH₂—CH₂—. Methylene in the alkylene and the arylene is unreplaced or replaced with oxy, preferably unreplaced. However, when replaced with oxy, the oxy does not directly bond to Si in the formula (2-iii).
   na is 1 to 3, preferably 2 or 3, more preferably 3.

Among the bonds of the linking group of the formula (a), the bonds that are not bonded to Si of the formula (2-iii) are bonded to Si contained in other repeating units.

The linking group represented by the formula (b) is as follows:

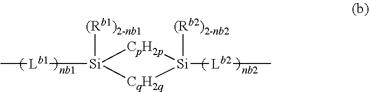

wherein,
R^{b1} and R^{b2} are each independently hydrogen, C₁₋₆ alkyl, C₁₋₆ alkenyl or C₆₋₁₂ aryl, preferably hydrogen or methyl.
   L^{b1} and L^{b2} are each independently C₂₋₈ alkylene or C₆₋₁₄ arylene, preferably C₂₋₆ alkylene, more preferably —CH₂—CH₂— or —CH₂—CH₂—CH₂—. Methylene in the alkylene and the arylene is unreplaced or replaced with oxy, preferably unreplaced. Provided that when replaced with oxy, the oxy does not directly bond to Si in the formula (2-iii).
   nb1 and nb2 are each independently 1 to 2, preferably 2.
   p and q are each independently 1 to 3, preferably 1 or 2, and more preferably 1.

Among the bonds of the linking group of the formula (b), the bonds that are not bonded to Si of the formula (2-iii) are bonded to Si contained in other repeating units.

The linking group represented by the formula (c) is as follows:

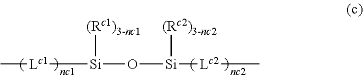

wherein,
R^{c1} and R^{c2} are each independently hydrogen, C₁₋₆ alkyl, C₁₋₆ alkenyl or C₆₋₁₂ aryl, preferably C₁₋₆ alkyl, more preferably methyl or ethyl.
   L^{c1} and L^{c2} are each independently C₂₋₈ alkylene or C₆₋₁₄ arylene, preferably C₂₋₆ alkylene, more preferably-CH₂—CH₂— or —CH₂—CH₂—CH₂—. Methylene in the alkylene and the arylene is unreplaced or replaced with oxy, preferably unreplaced. Provided that when replaced with oxy, the oxy does not directly bond to Si in the formula (2-iii).
   nc1 and nc2 are each independently 1 to 3, preferably 2.

Among the bonds of the linking group of the formula (c), the bonds that are not bonded to Si of the formula (2-iii) are bonded to Si contained in other repeating units.

The mass average molecular weight of the polycarbosilazane according to the present invention is preferably sufficiently large in order to prevent vaporization of low molecular weight components and suppress changes in volume when filled in fine trenches. On the other hand, a sufficiently low viscosity is preferred for sufficient coatability, and sufficient filling even in trenches with high aspect ratio. For these reasons, the mass average molecular weight of the polycarbosilazane is preferably 1,200 to 28,000, more preferably 1,500 to 25,000.

### Polysiloxazane

The structure of the polysiloxazane used in the present invention is not particularly limited, and any polysiloxazane can be freely selected depending on the purpose. The polysiloxazane has a siloxane bond in the polysilazane main skeleton, and preferably comprises a repeating unit represented by the following formula (3-i) and a repeating unit represented by the following formula (3-ii).

That is a siloxazane compound having repeating units represented below:

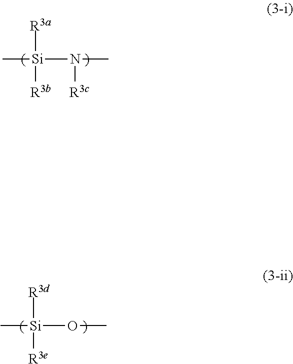

wherein,
R^{3a}, R^{3b}, R^{3c}, R^{3d} and R^{3e} are each independently a hydrogen atom, an alkyl group, an alkenyl group, a cycloalkyl group or an aryl group, at least one of R^{3a} and R^{3b} is a hydrogen atom, and at least one of R^{3d} and R^{3e} is a hydrogen atom, which is characterized by the following:

in the siloxazane compound, the ratio of O atoms to the total number of O atoms and N atoms is 5% or more and 25% or less, and in the spectrum of the siloxazane compound obtained by 29Si-NMR based on the inverse gate decoupling method, the ratio of the area of the peak detected at −75 ppm to −90 ppm to the area of the peak detected at −25 ppm to −55 ppm is 4.0% or less.

The mass average molecular weight of the polysiloxazane according to the present invention is preferably sufficiently large in order to prevent vaporization of low molecular weight components and suppress changes in volume when filled in fine trenches. On the other hand, a sufficiently low viscosity is preferred for sufficient coatability, and sufficient filling even in trenches with high aspect ratio. For these reasons, the mass average molecular weight of the polysiloxazane is preferably 1,200 to 28,000, more preferably 1,500 to 25,000.

### Solvent

The composition used in the present invention can comprise a solvent. This solvent is selected from those that uniformly dissolve or disperse each component contained in the composition. The solvent includes, for example, ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether (PGME) and propylene glycol monoethyl ether; propylene glycol alkyl ether acetates, such as propylene glycol monomethyl ether acetate (PGMEA), propylene glycol monoethyl ether acetate and propylene glycol monopropyl ether acetate; aromatic hydrocarbons, such as benzene, toluene, xylene and mesitylene; ethers, such as dipropyl ether, dibutyl ether and anisole; ketones, such as methyl ethyl ketone, acetone, methyl amyl ketone, methyl isobutyl ketone and cyclohexanone; alcohols, such as isopropanol and propanediol; and alicyclic hydrocarbons, such as cyclooctane and decalin. Xylene, dibutyl ether and propylene glycol monomethyl ether are preferred.

These solvents can be used alone or in combination of any two or more. The content of the solvent is preferably 1 to 96 mass %, more preferably 20 to 85 mass %, based on the total mass of the composition.

The composition used in the present invention can be combined with further optional components as necessary. The optional component includes, for example, surfactants. The content of the optional components excluding the solvent in the entire composition is preferably 10 mass % or less, more preferably 5 mass % or less, based on the total mass.

Hereinafter, the present invention is described with reference to Examples. These Examples are for explanation and do not intend to limit the scope of the present invention.

In the following Examples, the mass average molecular weight (Mw) is measured by the gel permeation chromatography (GPC) based on polystyrene. GPC is measured using Alliance (trademark) e2695 type high-speed GPC system (Nihon Waters K.K.) and an organic solvent-based GPC column Shodex KF-805 L (Resonac Corporation). The measurement is conducted using monodispersed polystyrene as a standard sample and chloroform as an eluent, under the measuring conditions of a flow rate of 0.6 ml/min and a column temperature of 40° C., and then Mw is calculated as a relative molecular weight to the standard sample.

### Preparation of Polysilazane Intermediate A

After replacing the inside of a 10 L reaction vessel equipped with a cooling condenser, a mechanical stirrer and a temperature controller with dry nitrogen, 7,500 ml of dry pyridine is added into the reaction vessel and it is cooled up to −3° C. Next, 500 g of dichlorosilane is added to form a white solid adduct (SiH₂Cl₂·2C₅H₅N). After confirming that the reaction mixture is cooled to −3° C. or lower, 350 g of ammonia is slowly blown into it while stirring. Subsequently, after continuing to stir for 30 minutes, dry nitrogen is blown into the liquid layer for 30 minutes to remove excess ammonia. The resulting slurry product is subjected to pressure filtration using a 0.2 μm filter made from Teflon (registered trademark) under a dry nitrogen atmosphere to obtain 6,000 ml of a filtrate. Pyridine is distilled off using an evaporator, and xylene is added to obtain a 39.8 mass % polysilazane intermediate xylene solution. The Mw of the polysilazane intermediate A obtained is 1,200.

### Preparation of Polycarbosilazane-Containing Composition A

After replacing the inside of a 1 L reaction vessel equipped with a cooling condenser, a mechanical stirrer and a temperature controller with dry nitrogen, 500 ml of dry pyridine is added into the reaction vessel and it is cooled up to −3° C. Next, 9.67 g of dichlorosilane and 4.33 g of 1,1,3,3-tetrachloro-1,3-disilacyclobutane are added. After confirming that the reaction mixture is cooled to 0° C. or lower, 10.3 g of ammonia is slowly blown into it while stirring. Subsequently, after continuing to stir for 30 minutes, dry nitrogen is blown into the liquid layer for 30 minutes to remove excess ammonia. The resulting slurry product is subjected to pressure filtration using a 0.2 μm filter made from Teflon (registered trademark) under a dry nitrogen atmosphere to obtain 400 ml of filtrate. After distilling off pyridine from the filtrate, xylene is added to obtain a 40.0 mass % of polycarbosilazane-containing composition A (hereinafter sometimes referred to as Composition A). The Mw of the polycarbosilazane obtained is 9,300.

### Preparation of Polycarbosilazane-Containing Composition B

In a 200 mL three-necked flask equipped with a magnetic stirrer bar, a nitrogen inlet and a reflux condenser, 30.0 g of the polysilazane intermediate A in xylene, 0.78 g of tetravinylsilane as a crosslinker in 8 g of toluene and 0.68 g of azabisisobutyronitrile (AIBN) as a reaction initiator are added, and xylene is further added so that the content of polysilazane intermediate A is 20 mass %, thereby preparing a reaction solution. While stirring, N₂ is blown into this for 10 minutes (50 mL/min). Thereafter, it is heated at 80° C. for 5 hours and concentrated at 40° C. under reduced pressure to obtain a 40.0 mass % of polycarbosilazane-containing composition B (hereinafter sometimes referred to as Composition B). The Mw of the polycarbosilazane obtained is 12,500.

### Preparation of Polysilazane-Containing Composition C

4,710 g of dry pyridine, 150 g of dry xylene and 1,650 g of the 39.8 mass % polysilazane intermediate A xylene solution obtained above are added, and the mixture is stirred while bubbling with nitrogen gas at 0.5 NL/min to achieve uniformity. Subsequently, a modification reaction is conducted at 110° C. for 10.0 hours to obtain a 41.0 mass % of polysilazane-containing composition C (hereinafter sometimes referred to as Composition C). The Mw of the polysilazane obtained is 7,800.

### Preparation of Polysiloxazane-Containing Composition D

After replacing the inside of a 10 L reaction vessel equipped with a cooling condenser, a mechanical stirrer and a temperature controller with dry nitrogen, 2,800 g of dry pyridine and 400 g of a xylene solution of the 39.8 mass % polysilazane intermediate are introduced, and the mixture is cooled up to −5° C. while stirring. Hydrous pyridine prepared by dissolving 6 g of pure water in 1,000 g of dry pyridine is added dropwise to the mixed solution cooled to −5° C. over 3 hours with stirring. After dropping, the solution is returned to room temperature and further stirred for one hour. After distilling off the pyridine, xylene is added to obtain a 19.8 mass % of polysiloxazane-containing composition D (hereinafter sometimes referred to as Composition D). The Mw of the polysiloxazane obtained is 5,800.

### Examples 1 and 2

Compositions A and B are each dropped on a silicon wafer (8 inches) having grooves (width: 2 μm, length: 20 μm and depth: 13 μm) and spin-coated at a rotation speed of 100 rpm to form a coating film. The formed coating film is made thick in the area having no grooves and it is not flat. The surplus part of the coating film adhered on the area having no grooves is removed. Next, the coating film is dried by prebaking on a hot plate at 80° C. for 90 seconds in N₂ atmosphere. Thereafter, the wafer is exposed for 30 minutes at 100° C. under atmospheric pressure to an atmosphere containing 15.0 kPa of NH₃ and having a water vapor partial pressure of 48.0 kPa. Next, using a thermal diffusion furnace, heating is performed at 350° C. for 60 minutes in an 80% water vapour atmosphere (the remainder being O₂) to obtain a siliceous film. Subsequently, annealing is performed at 850° C. for 30 minutes in N₂ atmosphere.

Using an optical microscope, it is observed whether or not cracks have generated in the area having grooves of the patterned substrate returned to room temperature.

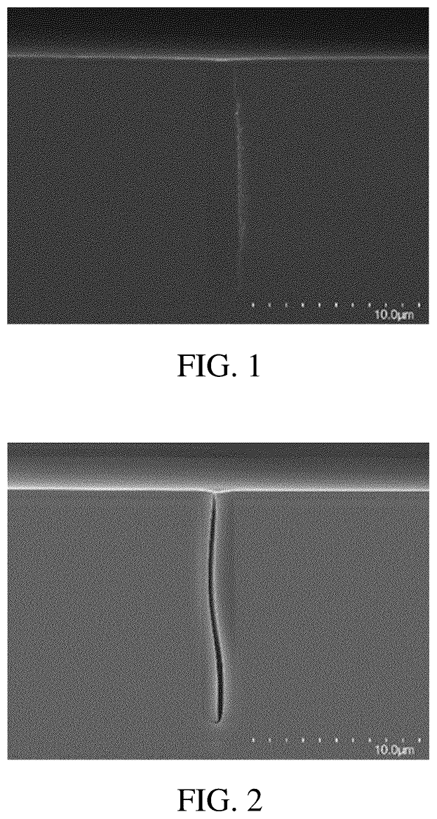

An electron micrograph of a cross section of the area having grooves of Example 1 is FIG. 1. From FIG. 1, it can be seen that in Example 1, there are no generation of cracks in the grooves and the grooves are filled uniformly.

The dry etching rate in the grooves in Example 1 is uniform in the grooves and 360 nm/min by inductively coupled plasma reactive ion etching (ICP-RIE) under the conditions of pressure: 2.68 Pa, output: 500 W, bias: 200 W, Ar: 100 sccm, CHF₃: 26 sccm, and CF₄: 34 sccm.

### Example 3

Using Composition A, a coating film is formed in the same manner as in Example 1, the surplus part is removed, prebaking is performed, and the coating film is dried. Thereafter, the wafer is exposed for 30 minutes at 100° C. under atmospheric pressure to an atmosphere containing 15.0 kPa of NH₃ and having a water vapor partial pressure of 48.0 kPa. Next, using a thermal diffusion furnace, heating is performed at 350° C. for 60 minutes in an 80% steam atmosphere to obtain a siliceous film. Subsequently, annealing is performed at 850° C. for 30 minutes in N₂ atmosphere.

In the same way as above, it is observed whether or not cracks have generated in the area having grooves.

### Example 4

Composition C is dropped on a silicon wafer (8 inches) having grooves (width: 0.15 μm, length: 2 mm and depth: 3 μm) and spin-coated at a rotation speed of 100 rpm to form a coating film. In the same manner as above, the surplus part is removed, prebaking is performed, and the coating film is dried. Thereafter, the wafer is exposed for 30 minutes at 80° C. under atmospheric pressure to an atmosphere containing 10.8 kPa NH₃ and having a water vapor partial pressure of 65.0 kPa. Next, using a thermal diffusion furnace, heating is performed at 350° C. for 60 minutes in an 80% steam atmosphere to obtain a siliceous film. Subsequently, annealing is performed at 850° C. for 30 minutes in N₂ atmosphere.

In the same way as above, it is observed whether or not cracks have generated in the area having grooves.

### Example 5

In the manner way as in Example 4, a coating film is formed on a wafer, the surplus part is removed, and the coating film is dried. Thereafter, the wafer is exposed for 30 minutes at 100° C. under atmospheric pressure to an atmosphere containing 2.3 kPa tetraethylammonium hydroxide and having a water vapor partial pressure of 80.0 kPa. Subsequently, annealing is performed at 850° C. for 30 minutes in N₂ atmosphere to obtain a cured film.

In the same way as above, it is observed whether or not cracks have generated in the area having grooves.

### Example 6

Composition D is dropped on a silicon wafer (8 inches) having grooves (width: 0.02 μm, length: 2 mm and depth: 0.5 μm) and spin-coated at a rotation speed of 1,000 rpm to form a coating film. In the same manner as above, the surplus part is removed, and the coating film is dried. Thereafter, the wafer is exposed for 30 minutes at 120° C. under atmospheric pressure to an atmosphere containing 22.0 kPa NH₃ and having a water vapor partial pressure of 32.0 kPa. Next, using a thermal diffusion furnace, heating is performed at 350° C. for 60 minutes in an 80% steam atmosphere to obtain a siliceous film. Subsequently, annealing is performed at 850° C. for 30 minutes in N₂ atmosphere.

In the same way as above, it is observed whether or not cracks have generated in the area having grooves.

### Comparative Examples 1 and 2

Using Compositions A and B, a coating film is formed in the same manner as in Example 1, the surplus part is removed, prebaking is performed, and the coating film is dried. The wafer is then exposed for 30 minutes at 100° C. under atmospheric pressure to an atmosphere having a water vapor partial pressure of 48.0 kPa (the remainder being N₂). Next, using a thermal diffusion furnace, heating is performed at 350° C. for 60 minutes in an 80% steam atmosphere to obtain a siliceous film. Subsequently, annealing is performed at 850° C. for 30 minutes in N₂ atmosphere.

In the same way as above, it is observed whether or not cracks have generated in the area having grooves.

An electron micrograph of a cross section of the area having grooves of Comparative Example 1 is FIG. 2. From FIG. 2, it can be seen that in Comparative Example 1, cracks are generated in the grooves and the grooves are not uniformly filled.

### Comparative Example 3

Using Composition A, a coating film is formed in the same manner as in Example 1, the surplus part is removed, prebaking is performed, and the coating film is dried. Thereafter, it is exposed for 30 minutes at 100° C. under atmospheric pressure to an atmosphere containing 15.0 kPa triethylamine and having a water vapor partial pressure of 48.0 kPa. Next, using a thermal diffusion furnace, heating is performed at 350° C. in an 80% steam atmosphere for 60 minutes to obtain a siliceous film. Subsequently, annealing is performed at 850° C. for 30 minutes in N₂ atmosphere.

In the same way as above, it is observed whether or not cracks have generated in the area having grooves.

### Comparative Example 4

In the same manner as in Example 4, a coating film is formed, the surplus part is removed, prebaking is performed, and the coating film is dried. Thereafter, the wafer is exposed for 30 minutes at 80° C. under atmospheric pressure to an atmosphere having a water vapor partial pressure of 65.0 kPa. Next, using a heathermal diffusion furnace, heating is performed at 350° C. in an 80% steam atmosphere for 60 minutes to obtain a siliceous film. Subsequently, annealing is performed at 850° C. for 30 minutes in N₂ atmosphere.

In the same way as above, it is observed whether or not cracks have generated in the area having grooves.

### Comparative Example 5

In the same manner as in Example 4, a coating film is formed, the surplus part is removed, prebaking is performed, and the coating film is dried. Thereafter, the wafer is exposed for 30 minutes at 80° C. under atmospheric pressure to an atmosphere containing 10.8 kPa of triethylamine and having a water vapor partial pressure of 65.0 kPa. Next, using a thermal diffusion furnace, heating is performed at 350° C. in an 80% steam atmosphere for 60 minutes to obtain a siliceous film. Subsequently, annealing is performed at 850° C. for 30 minutes in N₂ atmosphere.

In the same way as above, it is observed whether or not cracks have generated in the area having grooves.

### Comparative Example 6

In the same manner as in Example 6, a coating film is formed, the surplus part is removed, prebaking is performed, and the coating film is dried. Thereafter, the wafer is exposed for 30 minutes at 120° C. under atmospheric pressure to an atmosphere having a water vapor partial pressure of 32.0 kPa. Next, using a thermal diffusion furnace, heating is performed at 350° C. in an 80% steam atmosphere for 60 minutes to obtain a siliceous film. Subsequently, annealing is performed at 850° C. for 30 minutes in N₂ atmosphere.

In the same way as above, it is observed whether or not cracks have generated in the area having grooves.

### Film Thickness Shrinkage Rate

Each composition is applied on a 4-inch high-resistance n-type Si wafer using a spin coater 1HDX2 (Mikasa Co., Ltd.) and spin-dried to produce a coating film. The film thickness is measured using a spectroscopic ellipsometer M-2000V (J.A. Woollam). Under the conditions of Examples and Comparative Examples, films after annealing are produced and each film thickness is measured. The difference between the coating film thickness and the film thickness after annealing divided by the coating film thickness is the film thickness shrinkage rate.

TABLE 1
Table 1

| | | | Step (b) | | | Film | | |
|---|---|---|---|---|---|---|---|---|
| | | | | Water vapor | | thickness | | |
| | | | Basic | partial | | shrinkage | Groove | |
| | | | compound | pressure | Temperature | rate | depth | |
| | | Composition | (kPa) | (kPa) | (° C.) | (%) | (μm) | Cracks |
| Example | 1 | Composition A | 15.0 | 48.0 | 100 | 25.9 | 13 | No |
| | | | NH₃ | | | | | |
| | 2 | Composition B | 15.0 | 48.0 | 100 | 24.5 | 13 | No |
| | | | NH₃ | | | | | |
| | 3 | Composition A | 15.0 | 48.0 | 100 | 25.2 | 13 | No |
| | | | NH₃ | | | | | |
| | 4 | Composition C | 10.8 | 65.0 | 80 | 18.8 | 3 | No |
| | | | NH₃ | | | | | |
| | 5 | Composition C | 2.3 | 80.0 | 80 | 19.1 | 3 | No |
| | | | TEAH | | | | | |
| | 6 | Composition D | 22.0 | 32.0 | 120 | 30.8 | 0.5 | No |
| | | | NH₃ | | | | | |
| Comparative | 1 | Composition A | — | 48.0 | 100 | 48.1 | 13 | Yes |
| Example | 2 | Composition B | — | 48.0 | 100 | 46.5 | 13 | Yes |
| | 3 | Composition A | 15.0 | 48.0 | 100 | 45.8 | 13 | Yes |
| | | | triethylamine | | | | | |
| | 4 | Composition C | — | 65.0 | 80 | 23.7 | 3 | Yes |
| | 5 | Composition C | 10.8 | 65.0 | 80 | 21.9 | 3 | Yes |
| | | | triethylamine | | | | | |
| | 6 | Composition D | — | 32.0 | 120 | 33.4 | 0.5 | Yes |

What is claimed is:

1. A method for manufacturing a siliceous film, comprising:
a) applying a siliceous film composition above a substrate having grooves to form a composition layer;
b) exposing the composition layer to an atmosphere containing a basic compound gas and water vapor; and
c) heating the substrate to cure the composition layer,
wherein the basic compound is ammonia, a quaternary ammonium compound or a combination of any of these.

2. The method according to claim 1, wherein the step (b) is performed at a temperature of 20 to 200° C.

3. The method according to claim 1, wherein the partial pressure of the basic compound gas in the step (b) is 2 to 50 kPa.

4. The method according to claim 1, wherein the partial pressure of the water vapor in the step (b) is 20 to 90 kPa.

5. The method according to claim 1, wherein the siliceous film composition comprises a silicon-containing polymer selected from the group consisting of polysilazane, polycarbosilazane and polysiloxazane.

6. The method according to claim 5, wherein the silicon-containing polymer has a mass average molecular weight of 1,000 to 30,000.

7. The method according to claim 5, wherein the content of the silicon-containing polymer is 10 to 100 mass % based on the total mass of the siliceous film composition.

8. The method according to claim 1, wherein the siliceous film composition comprises a solvent.

9. The method according to claim 1, further comprising a step of heating the substrate above which the composition layer is formed at 50° C. or higher, between the step (a) and the step (b).

10. The method according to claim 1, wherein the heating in the step (c) is performed at 200 to 1,000° C.

11. A siliceous film obtained by the method according to claim 1.

12. An electronic device comprising the siliceous film according to claim 11.

13. A method for manufacturing an electronic device comprising the method according to claim 1.
